(19) United States
(12) Patent Application Publication
(10) Pub. No.: US 2010/0230776 A1
(43) Pub. Date: Sep. 16, 2010

(54) SEMICONDUCTOR STRUCTURE AND METHOD OF MANUFACTURE

(76) Inventor: Bishnu Prasanna Gogoi, Scottsdale, AZ (US)

Correspondence Address: HVVI SEMICONDUCTORS, INC., c/o CPA Global, P.O. BOX 52050, MINNEAPOLIS, MN, 55402, US

(21) Appl. No.: 12/330,746

(22) Filed: Dec. 9, 2008

Related U.S. Application Data
(60) Provisional application No. 61/012,873, filed on Dec. 11, 2007.

(51) Int. Cl. H01L 29/02; H01L 21/70; H01L 29/06; H01L 21/02

(52) U.S. Cl. 257/506; 438/400; 257/528; 438/424; 257/E21.532; 257/E21.002; 257/E29.002; 257/E29.005

(57) ABSTRACT

Briefly, in accordance with one or more embodiments, a semiconductor structure and method for forming the semiconductor structure are disclosed. The semiconductor structure may comprise a dielectric structure and one or more active areas or one or more field areas, for example, disposed proximate to the dielectric structure along a perimeter thereof. The dielectric structure and the other areas may be separated by one or more trenches or gaps to provide stress relief between the dielectric structure and the other areas. The one or more trenches may include one or more silicon formations formed there between to provide a spring like function and further provide stress relief between the dielectric structure and the other areas. Stress relief of the trenches may be further enhanced via hydrogen annealing to smooth sharp corners or other sharp features of the trenches such as scalloping.

### CROSS-REFERENCE TO RELATED APPLICATIONS

The present application claims the benefit of U.S. Provisional Application No. 61/012,873 filed Dec. 11, 2007.

### TECHNICAL FIELD

Embodiments disclosed in the present disclosure relate generally to electrical and semiconductor technology, and more specifically to a semiconductor structure that includes a dielectric structure.

### BACKGROUND

For some applications, such as high frequency or radio frequency (“RF”) applications, integrated passive devices may be formed using semiconductor processing technology or it may be desirable to integrate passive devices such as inductors and/or capacitors together with active devices such as transistors using conductive silicon substrates. However, passive devices may have relatively low quality factors (“Qs”) when these passive devices are formed on, or in relatively close proximity to, the conductive silicon substrate. In addition, due to parasitic capacitive coupling between these passive devices and the conductive silicon substrate, the frequency of operation of the integrated devices is reduced. Electrically conductive interconnects or busses may be used to electrically couple different devices within the die and external to the die. The frequency of operation may also be reduced by parasitic capacitive coupling between the interconnects and the conductive silicon substrate

Further, regions of a semiconductor substrate may be physically and electrically isolated from each other. Additionally, some semiconductor devices, such as power transistors, provide relatively high output power which may be utilized in some RF, industrial, and medical applications. Power transistor designers are continually seeking ways to efficiently increase output power by varying the output voltage and current characteristics of a power transistor. For example, a power transistor may have an increased breakdown voltage to enable the power transistor to operate at a relatively higher voltage and provide a relatively higher output power.

### DESCRIPTION OF THE DRAWING FIGURES

Claimed subject matter is particularly pointed out and distinctly claimed in the concluding portion of the specification. However, such subject matter may be understood by reference to the following detailed description when read with the accompanying drawings in which:

FIG. 1 is a cross-sectional view of a semiconductor structure substrate in which one or more stress relieving trenches may be formed in such a manner that silicon remaining between the trenches may be formed to have a certain structural shape in accordance with one or more embodiments;

FIG. 2 is a cross-sectional view of the semiconductor structure of FIG. 1 showing one or more masking layers formed thereon in accordance with one or more embodiments;

FIG. 3 is a cross-sectional view of the semiconductor structure of FIG. 1 showing one or more stress relieving trenches formed therein in accordance with one or more embodiments;

FIG. 4 is a top plan view of the semiconductor substrate of FIG. 1 showing the formation of one or more stress relieving trenches formed in such a manner that silicon remaining between the trenches may have a certain structural shape at the perimeters of various regions of the semiconductor structure in accordance with one or more embodiments;

FIG. 5 is a detailed top plan view of several formations of silicon having certain structural shapes formed between trenches as result of the formation of stress relief trenches in the semiconductor structure of FIG. 1 in accordance with one or more embodiments;

FIG. 6 is a cross-sectional view of stress relieving trenches formed in the semiconductor substrate of FIG. 1 showing various features at which further stress relieving actions, such as hydrogen annealing, may be taken in accordance with one or-more embodiments;

FIG. 7 is a cross-sectional view of stress relieving trenches formed in the semiconductor substrate of FIG. 1 showing various features at which further stress relieving actions, such as hydrogen annealing, have been taken in accordance with one or more embodiments;

FIG. 8 is a cross-sectional view of the semiconductor structure of FIG. 1 showing a thin oxide layer grown in the stress relief trenches thereof in accordance with one or more embodiments;

FIG. 9 is a cross-sectional view of the semiconductor structure of FIG. 1 showing the deposition of a non-conformal film and a conformal film to seal the trenches thereof in accordance with one or more embodiments;

FIG. 10 is a cross-sectional view of the semiconductor structure of FIG. 1 showing further etching of the stress relief trenches for forming a dielectric structure in accordance with one or more embodiments;

FIG. 11 is a cross-sectional view of the semiconductor structure of FIG. 1 shoving the oxidation of the sidewalls of the dielectric structure trenches in accordance with one or more embodiments;

FIG. 12 is a cross-sectional view of the semiconductor structure of FIG. 1 showing the filling of the dielectric structure trenches in accordance with one or more embodiments;

FIG. 13 is a cross-sectional view of the semiconductor structure of FIG. 1 showing oxidation of the fill material as shown in FIG. 12 in accordance with one or more embodiments; and

FIG. 14 is a cross-sectional view of the semiconductor structure of FIG. 1 showing the formation of an active area and/or a field area in accordance with one or more embodiments.

For simplicity of illustration and ease of understanding, elements in the various figures are not necessarily drawn to scale, unless explicitly so stated. Further, if considered appropriate, reference numerals have been repeated among the figures to indicate corresponding and/or analogous elements.

### DETAILED DESCRIPTION

In some instances, well-known methods, procedures, components and circuits have not been described in detail so as not to obscure the present disclosure. The following detailed description is merely exemplary in nature and is not intended to limit the disclosure of this document and uses of the disclosed embodiments. Furthermore, there is no intention that the appended claims be limited by the title, technical field, background, or abstract.

In the following description and/or claims, the terms coupled and/or connected, along with their derivatives, may be used. In particular embodiments, connected may be used to indicate that two or more elements are in direct physical and/or electrical contact with each other. Coupled may mean that two or more elements are in direct physical and/or electrical contact. However, coupled may also mean that two or more elements may not be in direct contact with each other, but yet may still cooperate and/or interact with each other. For example, “coupled” may mean that two or more elements do not contact each other but are indirectly joined together via another element or intermediate elements. Finally, the terms “on,” “overlying,” and “over” may be used in the following description and claims. “On,” “overlying,” and “over” may be used to indicate that two or more elements are in direct physical contact with each other. However, “over” may also mean that two or more elements are not in direct contact with each other. For example, “over” may mean that one element is above another element but not contact each other and may have another element or elements in between the two elements. On may also include in or at least partially’ in. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect. In the following description and/or claims, the terms “comprise” and “include,” along with their derivatives, may be used and are intended as synonyms for each other.

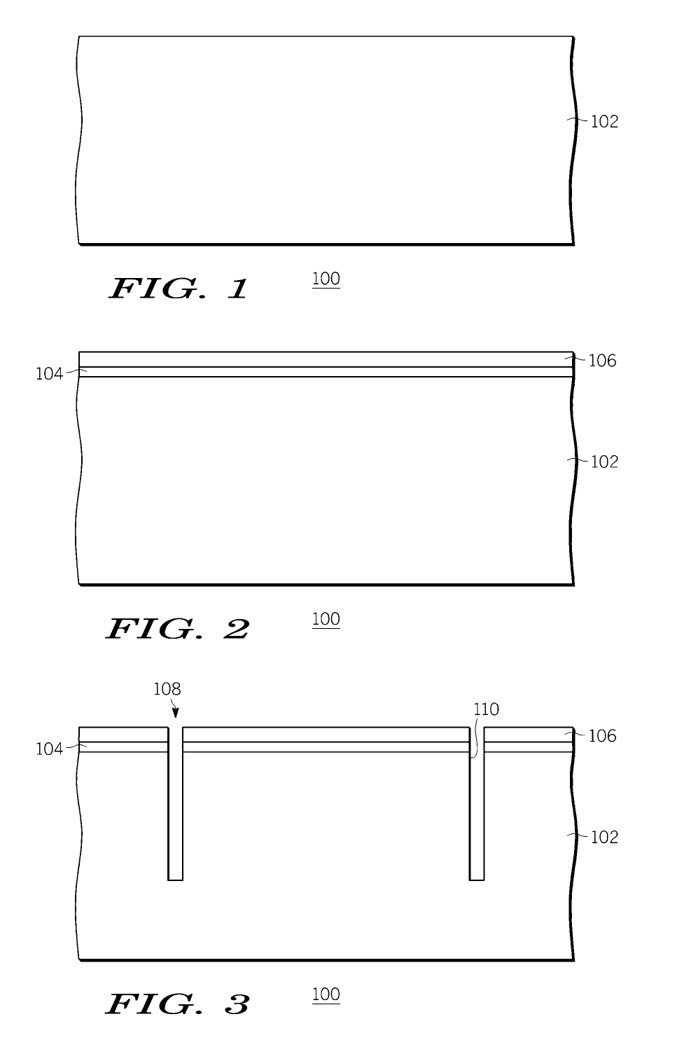

Referring now to FIGS. 1-14, a method for forming a semiconductor structure and the resulting semiconductor structure comprising a dielectric structure, one or more discontinuous trenches, and one or more structural silicon shapes between the trenches in accordance with one or more embodiments will be discussed. As shown in FIG. 1, semiconductor structure 100 may be formed by providing a starting substrate 102 which may comprise a semiconductor type material such as silicon. As shown in FIG. 2, one or more masking layers may be added to substrate 102, for example oxide layer 104, comprising silicon dioxide (SiO₂), and/or nitride layer 106, comprising silicon nitride (Si₃N₄). In one or more embodiments, oxide layer 104 and/or nitride layer 106 may be formed using chemical vapor deposition (CVI)) and/or low-pressure chemical vapor deposition (LPCVD), for example to act as a hard mask when forming trenches, although the scope of the claimed subject matter is not limited in these respects. Nitride layer 106 may be utilized to provide insulation and/or to serve as a chemical barrier during the formation of the remainder of semiconductor structure 100.

Referring now to FIG. 3, one or more trenches 108 may be etched into substrate 102 through the masking layers such as oxide layer 104 and/or nitride layer 106. Alternatively, trenches 108 may be referred to as voids, gaps, cavities, an empty region, an empty space, and so on, although the scope of the claimed subject matter is not limited in this respect. In general, trenches may be referred to as gaps, which may be filled for example with oxide, may be capped or sealed, may contain a gas or air, or may he at least partially evacuated, however the scope of the claimed subject matter is not limited in these respects. In one or more embodiments, trenches 108 may be formed via deep reactive ion etching (DRIE) to produce trenches having a depth ranging from approximately three microns to approximately 30 microns, and having a width ranging from about one micron to approximately two microns. However, these are merely example dimensions for trenches 108, and the scope of the claimed subject matter is not limited in these respects.

Photolithography processes or operations involve the use of masks and may sometimes be referred to as masking operations or acts. The photolithography and etching may include forming a layer of a radiation-sensitive material, Such as photoresist (not shown), on semiconductor Structure 100, then exposing the photoresist using, for example, ultraviolet (UV) radiation to form a mask, and then etching portions of layers 104 and 106 using a reactive ion etch, a wet etch, or combinations thereof, to form openings, trenches, or cavities 108.

Trenches 108 may be etched using a wet chemical etch or a dry etch process such as, for example, a reactive ion etch (RIE) and/or deep reactive ion etch (I)RIE). The etching of substrate 102 may form sidewalls of trenches 108 that are relatively straight or vertical. After the etching of substrate 102, the photoresist (not shown) may be stripped or removed.

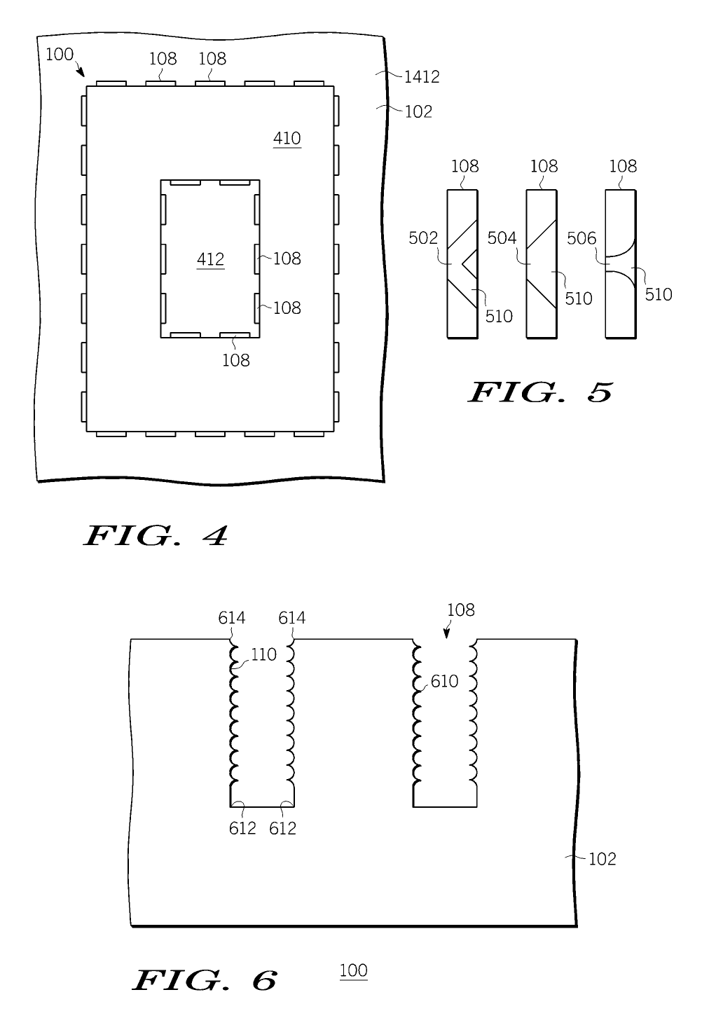

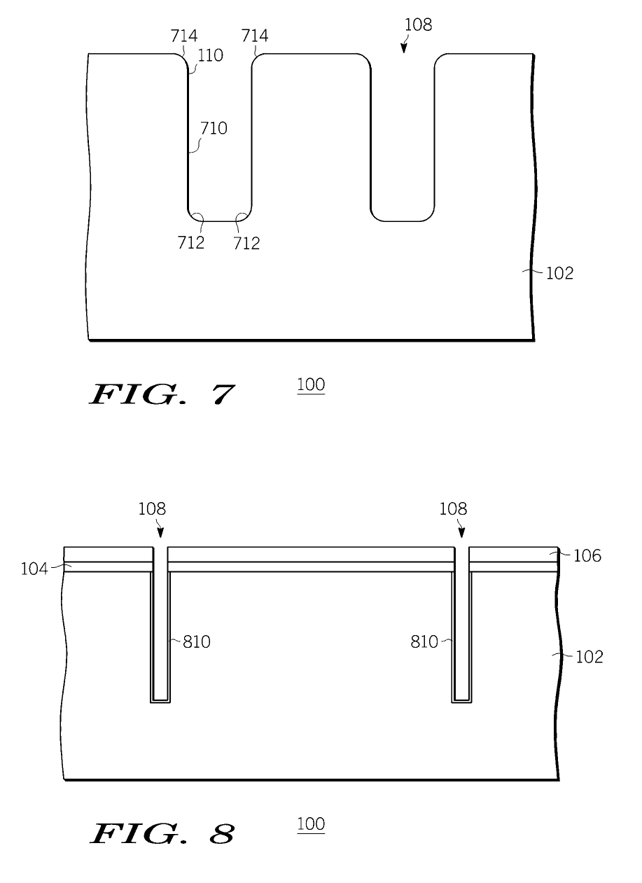

A sample arrangement of trenches 108 in substrate 102 is shown in and described with respect to FIG. 4, below. In one or more embodiments, trenches 108 may be etched to include one or more silicon formations (not shown in FIG. 3) between trenches 108 in order to provide reduced stress. Details of such silicon formations having certain structural shapes between trenches are described with respect to FIG. 5, below. In one or more embodiments, features and/or the topography of trenches 108 may be shaped for example using hydrogen annealing to further provide reduced stress, as shown in and described with respect to FIGS. 6 and 7, below. Referring back to FIG. 34, stress that may be reduced in one or more embodiments as described herein may result from, for example, etching processes, oxidation processes in which oxide is grown, and/or chemical growth processes that may result in edges on the surface of a structure that are no longer in equilibrium and/or may result in a mismatch in coefficients of thermal expansion (CTE) when two adjacent materials are thermal cycled. Furthermore, dielectric structure 410 (FIGS. 4 and 14) may comprise a filled structure Ior example filled with oxide where again a mismatch in the coefficient of thermal expansion between the oxide material of dielectric structure 410 and silicon in an adjacent structure or region such as active area 412 (FIGS. 4 and 14) may cause dielectric structure to impart stress upon active area 412 when semiconductor structure 100 is thermal cycled. Such stress imparted by dielectric structure 410 upon active area 412 may result in defects in the silicon of active area 412 that may cause undesirable leakage currents in devices formed in active area 412 via dislocations. By using trenches 108 disposed between dielectric structure 410 and other regions adjacent to dielectric structure 410 such as active area 412, stress imparted upon the other regions by dielectric structure 410 may be reduced and/or eliminated to result in more robust devices in active area 412 wherein undesirable leakage currents may be reduced and/or eliminated.

Trenches 108 may be formed at the perimeter of one or more regions or areas of semiconductor structure 100 and in particular may be formed at junctions between one region and another region, for example where the regions comprise different types of materials. It should be noted that in one embodiment, trenches 108 may be formed before dielectric structure 410 is formed, and in an alternative embodiment, trenches 108 may he formed after dielectric structure 410 is formed. Thus, trenches 108 may be formed at locations along a perimeter of a region that may be formed in one or more future steps of a process for manufacturing semiconductor structure 100. Trenches 108 may comprise air and/or other gases that are sealed in trenches 108 when semiconductor structure 100 is in a final or nearly final form. As such, trenches 108 may provide stress relief at junctures between material having different coefficients of thermal expansion (CTE) when semiconductor structure 100 is heated and/or cooled. In addition, as discussed herein, trenches 108 may provide desirable dielectric properties and may be formed and/or disposed at locations in semiconductor structure 100 to impart such desirable dielectric properties, although the scope of the claimed subject matter is not limited in these respects.

Referring again to FIG. 4, a top plan view of semiconductor structure 100 having one or more trenches with silicon having certain structural shapes between trenches for providing stress relief in accordance with one or more embodiments will be discussed. As shown in FIG. 4, semiconductor structure 100 may comprise substrate 102 that includes active area 412 and field area 1412 formed adjacent to dielectric structure 410. It should be noted that in one or more embodiments, active area 412 may be disposed inside dielectric structure 410, that is interiorly, and in one or more embodiments active area 412 may be disposed externally to dielectric structure 410, for example adjacent to or proximate to dielectric structure 410, and/or circumferentially surrounding dielectric structure 410, however the scope of the claimed subject matter is not limited in these respects. Dielectric structure 410 may be referred to as a dielectric structure or a dielectric region, and active area 412 may also be referred to as an active region. Active area 412 may comprise an area where active devices, such as, for example, transistors or diodes, or portions of active devices, may be subsequently formed. Active devices may be formed in active area 412, for example, by using conventional complementary metal oxide semiconductor (CMOS), bipolar, or bipolar-CMOS (BiCMOS) processes or the like.

In the embodiment shown in FIG. 4, active area 412 is disposed interiorly within dielectric structure 410. Alternatively, active area 412 may be disposed exteriorly to dielectric structure 410, or combinations of interiorly and exteriorly disposed. However, such an arrangement of active area 412 with respect to dielectric structure 410 is merely one example arrangement, and the scope of the claimed subject matter is not limited in this respect. In the particular embodiment of FIG. 4, one or more trenches 108 may circumscribe the perimeter of active area 412. In such an arrangement, trenches 108 may provide stress relief against stress imparted from dielectric structure 410 on active area 412. Likewise, one or more additional trenches 108 may circumscribe the perimeter of dielectric structure 410, also to provide stress relief to active area 412 from dielectric structure 410. One or more silicon regions having certain structural shapes between trenches as shown in FIG. 5 may be formed adjacent or abutting one or more of trenches 108. Utilizing one or more perimeter trenches 108 disposed between active area 412 and dielectric structure 410 provides separation of dielectric structure 410 from active area 412. Furthermore, perimeter trenches 108 are mechanically robust and serve to provide stress relief between dielectric structure 410 and active area 412, for example to allow stress relief of thermal expansion and/or contraction of dielectric structure 410 and active area 412 during heating and/or cooling of semiconductor structure 100. In addition, one or more additional active areas may be disposed exteriorally to dielectric structure 410 in one or more embodiments to likewise provide the same or similar benefits. In yet another embodiment, dielectric structure 410 may be centrally and/or interiorly disposed, and one or more active areas 412 may be disposed adjacent to and/or around dielectric structure 410, at least partially or completely circumferentially surrounding dielectric structure 410, using perimeter trenches 108 between dielectric structure 410 and one or more active areas 412 to provide the same or similar benefits as discussed herein. However, these are merely some example benefits provided by utilizing perimeter trenches 108, and the scope of the claimed subject matter is not limited in these respects.

As shown in FIG. 5, a top plan view of semiconductor structure 100 is shown illustrating silicon formations 510 having certain structural shapes between trenches via the formation of trenches 108 to provide additional stress relieving properties to alleviate stress forces that may occur between materials having different coefficients of thermal expansion. Such Silicon formations 510 remaining after formation of trenches 108 may comprise various structural shapes to provide spring-like resistance to expansion and/or contraction. For example, as shown in FIG. 5, silicon formations 510 may comprise a chevron type structure 502, a triangular type structure 504 and/or a conical, funnel and/or frustum type structure 506, or the like. In general, trenches 108 may be formed in such a manner that silicon remaining between trenches may have such certain structural shapes or formations. However, these are merely example structural shapes that silicon formations 510 may comprise, and the scope of the claimed subject matter is not limited in these respects. In one or more embodiments, silicon formations 510 may be formed between perimeter trenches 108 and between dielectric structure 410 and active area 412. Such silicon island 510 “springs” may be mechanically robust and provide mechanical stress relief to further enhance the stress relieving properties of perimeter trenches 108. Although some example designs of silicon formations 510 are shown in FIG. 5, different designs for silicon formations 510 may be implemented, (-or-example straight structures, angled structures, curved structures, folded structures, and so on, and the scope of the claimed subject matter is not limited in these respects. Such silicon formation 510 structures may be formed, for example, via the same and/or similar process used to form trenches 108 as shown in and described with respect to FIG. 3, although the scope of the claimed subject matter is not limited in these respects.

Referring now to FIG. 6, a cross-sectional view of stress relieving trenches formed in semiconductor substrate 102 of FIG. 1 showing various features at which further stress relieving actions may be taken in accordance with one or more embodiments will be discussed. As shown in FIG. 6, one or more trenches 108 may be formed in substrate 102 via a deep reactive ion etching (DRIE) type process or the like. The result of such a DRIF, etching process may result in trenches 108 having one or more sidewalls 110 with scallop type features 610 formed on the surface thereof. Such scallop type features 610 may be higher stress points, thereby resulting in lower stress relieving properties of trenches 108, for example stress fractures may be formed at scallop type features 610 and which may reduce the mechanical integrity of semiconductor structure 100. Likewise, DRIE type etching may result in sharp edged corners 612 and/or 614 at the bottom and top regions ol trenches 108 which may also be higher stress points, where the exterior convex corners may generally result in more stress than interior concave corners. Such undesirable stress points may be reduced and/or eliminated via hydrogen annealing as shown in and described with respect to FIG. 7.

Referring now to FIG. 7, a cross-sectional view of stress relieving trenches formed in semiconductor substrate 102 of FIG. 1 showing various features at which further stress relieving actions has been taken in accordance with one or more embodiments will be discussed. In one or more embodiments, after trenches 108 are formed, stress points such as scalloping type feature 610, and sharp edged corners 612 and/or 614 may be reshaped and smoothed via a hydrogen annealing type process. Hydrogen annealing may result in an increased surface mobility of silicon at temperatures lower than the melting point of silicon. The increased surface mobility the silicon atoms may allow surface atoms to migrate and become more stable, resulting in a smoothened surface of the silicon. Thus, the scalloping of sidewalls formed using DRIE may be reduced and/or eliminated, resulting in smoother sidewalls, wherein the sidewalls are planar or substantially planar. Likewise, sharper corners may be smoothed into more rounded corners. In general, sharp or angular silicon structures may be become smoother and rounder via hydrogen annealing. The smoother and rounder shapes of sidewalls and corners contribute less stress than scalloped sidewalls and sharp corners. In such a hydrogen annealing process, silicon may be annealed in hydrogen ambient at a selected temperature and pressure for an annealing time selected to result in the desired amount of smoothing and rounding of the silicon. For example, hydrogen annealing may be implemented in one or more embodiments at a temperature ranging from about 1000 degrees Celsius to about 1100 degrees Celsius, at a pressure from about 10 Ton to about 1000 Torr, and for an annealing time from about one minute to about 20 minutes. In one particular embodiment, hydrogen annealing may be performed at a pressure of about 10 Ton and a temperature of about 1000 degrees Celsius for about five minutes to result in a feature corner radius of curvature of about 0.5 microns, and in another particular embodiment, hydrogen annealing may be performed at a pressure of about 10 Ton and a temperature of about 1100 degrees Celsius for about 10 minutes to result in a feature corner radius of curvature of about 1.0 microns. Furthermore, the silicon flow rate may be controlled via selecting the temperate and pressure at which hydrogen annealing is performed to arrive at a desirable surface diffusion coefficient. For example, at an annealing temperature of about 1000 degrees Celsius, the surface diffusion coefficient may be between 10⁶ and 10⁷ nm²/s at about 100 Ton, and may be between 10⁴ and 10⁵ nm²/s at about 1000 Ton. However, these are merely example parameters for performing hydrogen annealing, and the scope of the claimed subject matter is not limited in these respects.

As a result of hydrogen annealing, trenches 108 formed in substrate 102 may have smoother surfaces 710 on trench sidewalls, and may have rounded corners 712 and 714 to reduce and/or eliminate the stress points resulting from DRIE type etching or the like. The degree of smoothness of surfaces 710 and the curvature of rounded edges 712 and/or 714 may be controlled by via control of the temperature and/or pressure at which the hydrogen annealing process is performed.

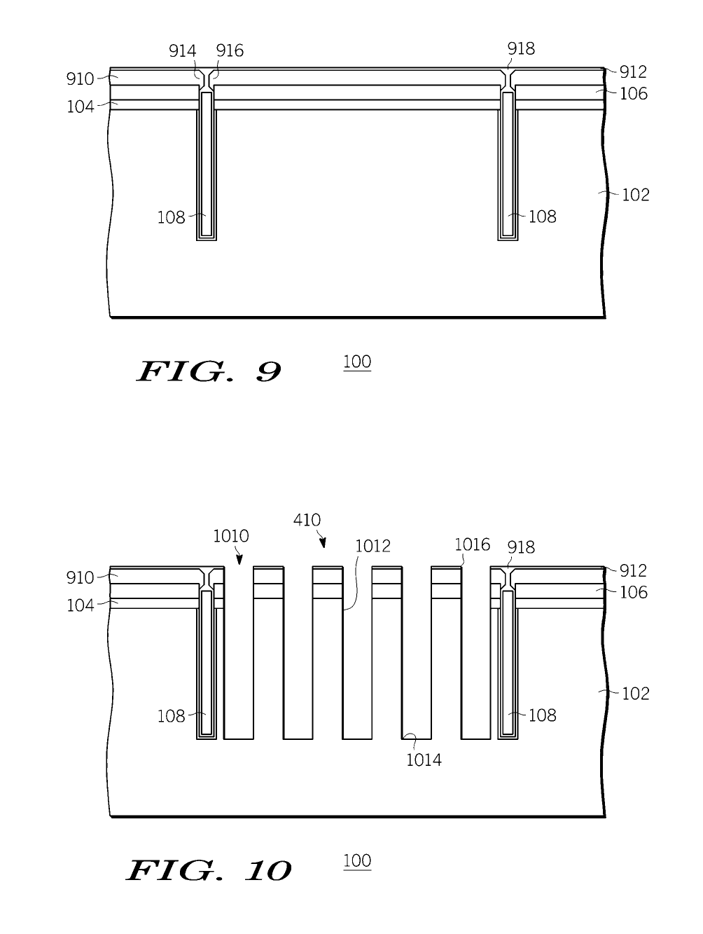

Referring now to FIGS. 8 and 9, cross-sectional views of the semiconductor Structure of FIG. 1 showing a thin oxide layer grown in the stress relief trenches thereof and then the deposition of conformal and non-conformal films to seal the trenches in accordance with one or more embodiments will be discussed. As shown in FIG. 8 a thin oxide layer 810 may be grown on the sidewalls of trenches 108 using, for example, a thermal oxidation process to convert an exposed portion of the silicon of substrate 102 to silicon dioxide. As shown in FIG. 9, a non-conformal film 910 such as a plasma enhanced chemical vapor deposition (PECVD) oxide may then be disposed over nitride layer 106. In one or more embodiments, non-conformal film 910 may be formed to at least partially seal, but not completely seal, trenches 108 so that adjacent ends 914 and 916 of non-conformal film 910 may be close but not touching one another. Such an arrangement allows a gap 918 to be formed at the open ends of trenches 108 so that a subsequent deposition of a conformal film 912 such as a low-pressure chemical vapor deposition high temperature oxide (LPCVD HTO) may be formed on the sidewalls of trenches 108 and also to completely seal trenches 108 while forming a layer of oxide on non-conformal film 910. Conformal film 912 may alternatively comprise low-pressure chemical vapor deposition tetraethylorthosilicate (LPCVD TEOS), low-pressure chemical vapor deposition low temperature oxide (LPCVD LTO), and/or low-pressure chemical vapor deposition (LPCVD) silicon nitride, however the scope of the claimed subject matter is not limited in these respects. Sealing of the openings of trenches 108 via conformal film 912 may form an air gap within trenches 108 with the silicon formations 510 (FIG. 5) disposed between the trenches.

Referring now to FIG. 10, cross-sectional view of the semiconductor Structure of FIG. 1 showing further etching of the dielectric Structure trenches for forming a dielectric structure 410 (FIG. 14) in accordance with one or more embodiments will be discussed. One or more additional trenches 1010 may be etched in substrate 102, for example using deep ion reactive etching (DRIE) to form a main body for dielectric structure 410. In one or more embodiments, one or more trenches 1010 of dielectric structure 410 may be adjacent to and/or abutting silicon formations 510 between trenches 108. Furthermore, as shown in and described with respect to FIG. 6 and FIG. 7, hydrogen annealing or the like may be utilized to smooth sidewalls 1012 and corners 1014 and/or 1016 of trenches 1010 to provide additional stress relief for trenches 1010, and/or further to reduce or remove any artifacts of oxidation processes, for example birds beaks. In one or more embodiments, oxide layer 104 may have a thickness of about 500 angstroms to about 2000 angstroms, and nitride layer 106 may have a thickness of about 100 angstroms. Likewise, non-conformal layer 910 may have a thickness of about 0.5 microns to about two microns, and conformal layer 912 may have a thickness of about 0.1 microns to about one microns. Trenches 1010 may have a width ranging from about 0.5 microns to about three microns, and a depth of about three microns to about 50 microns. Furthermore, trenches 1010 may be spaced apart at a distance from about 0.5 microns to about two microns. The entirety of dielectric structure 410 may a width and/or length ranging from about five microns to about 100 microns, and may have a depth of about three microns to about 50 microns. In one or more embodiments, dielectric structure 410 may have a dielectric constant ranging from about two to about five, and in one example the dielectric constant may be around 3.9 which is the dielectric constant of silicon dioxide. Trenches 108 may have a width of about one micron to two microns and a depth from about three microns to about 30 microns. However, these are merely example feature dimensions for semiconductor structure 100, and the scope of-the claimed subject matter is not limited in these respects.

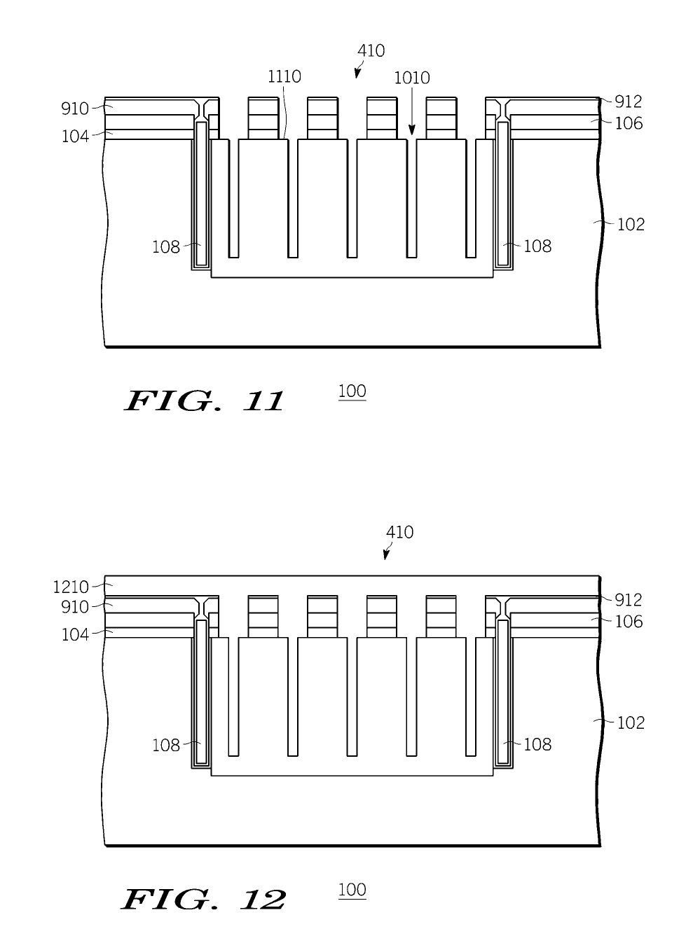

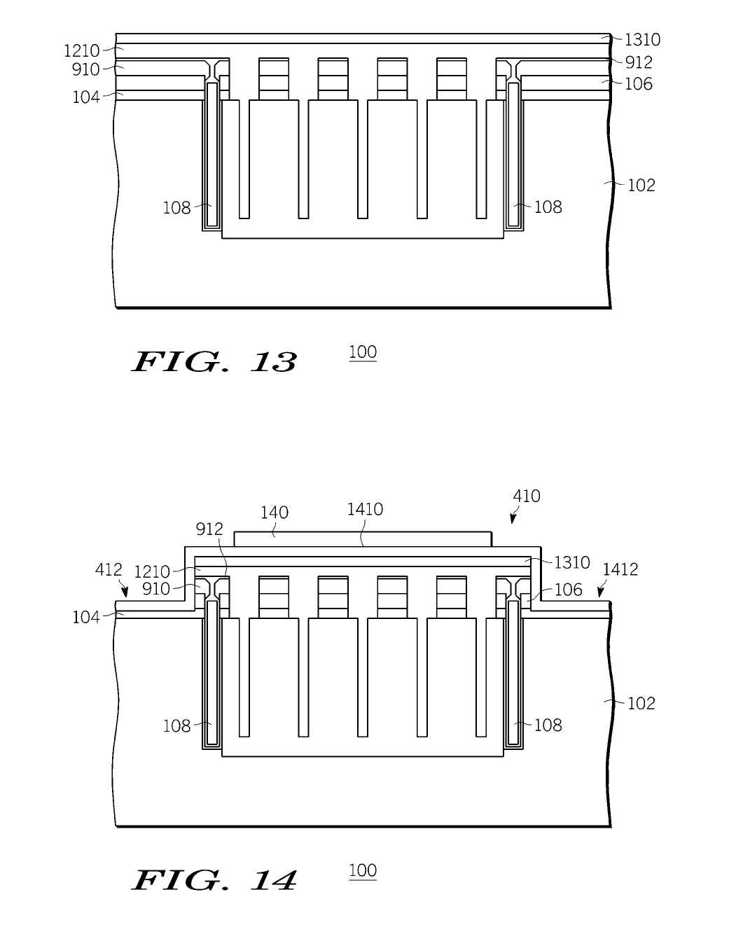

Referring now to FIG. 11, FIG. 12, and FIG. 13, cross-sectional views of semiconductor structure 100 showing the oxidation and refilling of the dielectric structure trenches in accordance with one or more embodiments will be discussed. Following formation of trenches 1010 in dielectric structure 410, the sidewalls of trenches 1010 may be oxidized by formation of silicon oxide within trenches 1010. Such oxidation may partially refill trenches 1010, or may fully refill or nearly refill trenches 1010. The amount of refill of trenches 1010 may be achieved by controlling the oxidation temperature, the oxidation time, and/or the sizes of trenches 1010. Such oxidation may comprise a wet oxidation process, a steam oxidation process, and/or a dry oxidation process. As shown in FIG. 12, trenches 1010 may then be refilled via low-pressure chemical vapor deposition (LPCVD) to deposit, for example, a polysilicon layer 1210. Alternatively, layer 1210 may comprise a LPCVD TEOS layer. Finally, as shown in FIG. 13, polysilicon layer 1210 may be oxidized to form an oxide layer 1310 to ensure, for example, that any remaining cavities or gaps may be sealed. However, these are merely example oxidation and/or deposition processes, and the scope of the claimed subject matter is not limited in these respects.

Referring now to FIG. 14, a cross-sectional view of the semiconductor structure of FIG. 1 showing the formation of an active area and/or a field area in accordance with one or more embodiments will be discussed. An active area may comprise a region where one or more active semiconductor devices may be disposed, for example transistors. A field area may comprise a region that may intentionally include no devices or elements, that may comprise a scribe grid area where semiconductor structure 100 may be cut into two or more dies, or may comprise process control monitor (PCM) type devices utilized as part of a semiconductor manufacturing process. Etching may be performed outside of dielectric structure 410 to form one or more active areas 412 and/or one or more field areas 1412. Such etching may include etching away masking layers such as nitride layer 106 and/or oxide layer 104 at regions of active areas 412 and/or field areas 1412. Subsequently, semiconductor structure 100 may be sealed with a conformal film 1410 such as low-pressure chemical vapor deposition (LPCVD) nitride or the like.

In some embodiments, it may be desirable for substrate 102 to be electrically conductive. For example, substrate 102 may serve as part of a drain region of a vertical transistor formed in active region 412. In this example, a source contact or electrode (not shown) may be formed on or adjacent to an upper surface of active area 412 and a drain electrode (not shown) may be formed on or adjacent to a lower surface of substrate 102. During operation, the electrical current flow from the source electrode to the drain electrode in the vertical transistor may be substantially perpendicular to the upper and lower surfaces of semiconductor structure 100. In other words, current flows essentially vertically through the vertical transistor from the electrode located adjacent a top surface of semiconductor structure 100 to a drain electrode located adjacent to the opposite bottom surface of semiconductor Structure 100. An example of a vertical transistor is described in U.S. patent application Ser. No. 10/557,135, entitled “POWER SEMICONDUCTOR DEVICE AND METHOD THEREFOR,” filed Nov. 17, 2005, which claims priority to Patent Cooperation Treaty (PCT) International Application Number PCTI/US2005/000205 entitled “POWER SEMICONDUCTOR DEVICE AND METHOD THEREFOR,” having an International Filing Date of Jan. 6, 2005 and an International Publication Date of Jul. 28, 2005, the contents of both of these patent applications are incorporated herein by reference in their entirety.

Although only a single active device is discussed as being formed in active area 412, the methods and apparatuses described herein are not limited in this regard. In some embodiments, one or more active devices may be formed in active area 412, although the scope of the claimed subject matter is not limited in this respect.

At least a portion of dielectric structure 410 may be formed below a top surface of Substrate 102. In some embodiments, a majority of dielectric Structure 410 is below the upper surface of substrate 102. In other embodiments, all of, or substantially all of, dielectric structure 410 is below the upper surface of substrate 410. Since in some embodiments at least a portion of dielectric structure 410 is formed in and below the upper surface of substrate 102, dielectric structure 410 may be referred to as an embedded dielectric structure in such embodiments. Embedded may mean that at least a portion of dielectric structure 410 is below a plane (not shown) that is coplanar to, or substantially coplanar to, the upper surface of substrate 102. In some embodiments, the portion of dielectric structure 410 below the plane extends from the plane to a depth of at least about three microns or greater below the plane and the portion of dielectric structure 410 below the plane has a width of at least about three microns or greater. In other words, at least a portion of dielectric platform 104 is embedded in substrate 410 and extends a distance of at least about three microns or greater from the upper surface of substrate 102 toward the bottom surface of substrate 102 and the portion of dielectric structure 410 embedded in substrate 102 has a width of at least about three microns or-greater in some embodiments.

In some embodiments sidewalls of trenches 108 or dielectric structure 410 adjacent or abutting active area 412 may serve as termination for equipotential lines during depletion of active devices formed in active area 412. Thus, equipotential lines impinge on these sidewalls. In other words, a termination structure comprising these sidewalls provides termination for equipotential lines from an electric field in active area 412 formed adjacent to the termination structure. It may be desirable for the sidewalls to be straight and smooth and perpendicular to the top surface of substrate 102 so that the electric field lines are substantially perpendicular to the sidewalls of trenches 108 and dielectric structure 410 adjacent or abutting active area 412, so that a condition that is referred to as planar breakdown is achieved where equipotential lines terminate at a perpendicular angle, or a substantially perpendicular angle, to the sidewalls.

Equipotential lines that impinge on the sidewalls at an angle that is not perpendicular to sidewalls may decrease the breakdown voltage of active devices formed in active area 412. In such an embodiment, it may be desirable to passivate the sidewalls with a high quality dielectric material such as a silicon dioxide formed using thermal oxidation of silicon.

Dielectric structure 410 may also be used to provide electrical isolation in semiconductor structure 100. For example, dielectric structure 410 may provide electrical isolation between active area 412 and field area 1412. In the example illustrated in FIG. 4, dielectric structure 410 may be formed to surround active area 412. Although a rectangular shaped active area 412 and a rectangular shaped dielectric structure 410 are illustrated in FIG. 4, the scope of claimed subject matter is not limited in this respect. In other embodiments, dielectric structure 410 and active area 412 may have any arbitrary shape. Although dielectric structure 410 illustrated in FIG. 4 is described as surrounding active area 410, the scope of claimed subject matter is not limited in this respect. In other embodiments, one or more dielectric platforms may surround none, or one or more of active areas and/or one or more dielectric platforms may be formed adjacent to or abutting, and not surrounding, a portion of one or more active areas.

Referring hack to FIG. 14, an electrically conductive material 140 may be formed over dielectric structure 410. Passive elements formed from conductive material 140 formed over dielectric structure 410 have reduced parasitic capacitances to substrate 102. The parasitic substrate capacitance is reduced by both the reduced effective dielectric constant of dielectric structure 410 and the increased thickness of dielectric structure 410. In one or more embodiments, at least a portion of dielectric structure 410 is between at least a portion of electrically conductive material 140 and at least a portion of substrate 102 to reduce capacitance between electrically conductive material 140 and substrate 102.

In addition, dielectric structure 410 may be used to increase the frequency of operation of any devices formed using semiconductor structure 100. For example, passive components such as, for example, inductors, capacitors, or electrical interconnects, may be formed over the embedded dielectric Structure 410 and may have reduced parasitic capacitive coupling between these passive components and substrate 102 since the embedded dielectric structure 410 has a relatively low dielectric constant or permittivity and since the embedded dielectric structure 410 increases the distance between the passive components and the conductive substrate. Reducing parasitic substrate capacitances may increase the frequency of operation of any devices formed using semiconductor structure 100. As an example, the passive component may comprise electrically conductive material 140, wherein electrically conductive material 140 may comprise, for example, aluminum, copper, or doped polycrystalline silicon, although the scope of the claimed subject matter is not limited in this respect. In various examples, the passive component may be an inductor, a capacitor, a resistor, or an electrical interconnect and may be coupled to one or more active devices formed in active area 412.

Further, dielectric structure 410 may be used to form relatively high quality passive devices such as, for example, capacitors and inductors having a relatively high quality factor (Q) since the dielectric structure 410 may be used to isolate and separate the passive devices from the Substrate. Active devices, such as transistors or diodes, may be formed in regions adjacent to, or abutting, the dielectric structure 410, and these active devices may be coupled to and employ passive components such as spiral inductors, interconnects, microstrip transmission lines and the like that are formed on a planar upper surface of dielectric structure 410. Separating the passive components from substrate 102 allows higher Qs to be realized for these passive components.

Although the claimed subject matter has been described with a certain degree of particularity, it should be recognized that elements thereof may be altered by persons skilled in the art without departing from the spirit and/or scope of claimed subject matter. It is believed that the subject matter pertaining to a perimeter trench for a dielectric structure and/or many of its attendant utilities will be understood by the forgoing description, and it will be apparent that various changes may be made in the forum, construction and/or arrangement of the components thereof without departing from the scope and/or spirit of the claimed subject matter or without sacrificing all of its material advantages, the form herein before described being merely an explanatory embodiment thereof, and/or further without providing substantial change thereto. It is the intention of the claims to encompass and/or include such changes.

What is claimed is:

1. A semiconductor structure, comprising:
a semiconductor material having a first surface and a second surface;
a dielectric structure, wherein at least a portion of said dielectric structure extends from the first surface to a distance of at least about three microns or greater below the first surface toward the second surface; and
said semiconductor material having a plurality of discontinuous claps formed therein abutting a perimeter of said dielectric structure.

2. A semiconductor structure as claimed in claim 1, said dielectric structure having a width or a length, or combinations thereof, of at least about live microns or greater.

3. A semiconductor structure as claimed in claim 1, wherein said dielectric structure is devoid of any gaps.

4. A semiconductor structure as claimed in claim 1, wherein one or more of the gaps have a width of about one micron to two microns.

5. A semiconductor structure as claimed in claim 1, wherein said dielectric structure has a width of about at least three microns or greater.

6. A semiconductor structure as claimed in claim 1, wherein each of the plurality of gaps is disposed between a portion of said semiconductor material and a portion of said dielectric structure.

7. A semiconductor structure as claimed in claim 1, wherein said semiconductor material comprises silicon.

8. A semiconductor structure as claimed in claim 1, wherein said dielectric structure has a dielectric constant of about two to five.

9. A semiconductor structure as claimed in claim 1, wherein said dielectric structure comprises silicon dioxide.

10. A semiconductor structure as claimed in claim 1, wherein said dielectric structure surrounds at least a portion of said semiconductor material.

11. A semiconductor structure as claimed in claim 1, wherein said semiconductor material comprises at least a portion of an active device in said semiconductor material.

12. A semiconductor structure as claimed in claim 11, wherein the active device comprises a first doped region in said semiconductor material and a second doped region in said semiconductor material.

13. A semiconductor Structure as claimed in claim 1, further comprising an electrically conductive material disposed on said dielectric structure, wherein at least a portion of said dielectric structure is disposed between at least a portion of said electrically conductive material and at least a portion of said semiconductor material to reduce capacitance between said electrically conductive material and said semiconductor material.

14. A semiconductor structure as claimed in claim 1, wherein the plurality of gaps are formed to result in remaining silicon between the plurality of gaps to have a structural shape being capable of reducing stress imparted on said semiconductor material by said dielectric structure.

15. A semiconductor structure as claimed in claim 14, wherein the structural shape of the remaining silicon between the plurality of gaps comprises a chevron type structure, a triangular type structure, a conical type structure, a funnel type structure, a frustum type structure, a straight type structure, an angled type structure, a curved type structure, or a folded type structure, or combinations thereof.

16. A semiconductor structure as claimed in claim 1, wherein each of the plurality of the gaps having a relatively planar sidewall or rounded corners, or combinations thereof, as a result of hydrogen annealing.

17. A semiconductor structure as claimed in claim 1, said dielectric structure comprising one or more trenches at least partially filled with an oxide material.

18. A semiconductor structure as claimed in claim 1, wherein one or more of the plurality of gaps being sealed and containing air, a gas, a vacuum, or a partial vacuum, or combinations thereof.

19. A semiconductor structure as claimed in claim 1, further comprising an active area or a Field area, or combinations thereof wherein one or more of the plurality of gaps are disposed adjacent in said active area or said field area, or combinations thereof, to reduce stress from said dielectric structure on said active area or said field area, or combinations thereof.

20. A method for forming a semiconductor structure, comprising:
etching a plurality of discontinuous craps in a substrate;
sealing the plurality of gaps; and
forming a dielectric structure to a depth of at least about three or more microns in the substrate, wherein the plurality of discontinuous daps abut the dielectric structure about a perimeter of the dielectric structure.

21. A method as claimed in claim 20, wherein said etching results in one or more silicon formations of silicon remaining between the plurality of gaps to have a structure capable of reducing stress caused by the dielectric structure on one or more other regions of the substrate.

22. A method as claimed in claim 20, said etching comprising deep reactive ion etching and wherein said forming occurs after said etching.

23. A method as claimed in claim 20, further comprising oxidizing sidewalls of the plurality of gaps prior to said sealing.

24. A method as claimed in claim 20, said sealing comprising depositing a non-conformal film or a conformal film, or combinations thereof, on the substrate to seal the plurality of gaps.

25. A method as claimed in claim 20, said etching or said forming, or combinations thereof, comprising hydrogen annealing one or more surfaces to result in relatively smoother surfaces or rounded corners, or combinations thereof.

26. A method as claimed in claim 20, said sealing comprising depositing a plasma enhanced chemical vapor deposition oxide, a low-pressure chemical vapor deposition tetraethylorthosilicate oxide, a low-pressure chemical vapor deposition high temperature oxide, a low-pressure chemical vapor deposition low temperature oxide, or a low-pressure chemical vapor deposition silicon nitride, or combinations thereof, on the substrate.

27. A method as claimed in claim 20, said forming a dielectric structure comprising etching one or more dielectric structure gaps adjacent to the plurality of gaps in the substrate to abut one or more of the silicon formations.

28. A method as claimed in claim 20, further comprising etching one or more active areas or one or more field areas, or combinations thereof, adjacent to the dielectric structure, wherein the plurality of gaps are disposed between the dielectric structure and the one or more active areas or the one or more field areas, or combinations thereof.

29. A method as claimed in claim 20, said etching the plurality of gaps and said forming the dielectric structure comprise disposing the plurality of gaps along an exterior perimeter of the dielectric structure, or along an interior perimeter of the dielectric structure, or combinations thereof.

30. A method as claimed in claim 20, said etching resulting in one or more silicon formations remaining between two or more of the plurality of gaps, the silicon formations having a chevron type structure, a triangular type structure, a conical type structure, a funnel type structure, a frustum type structure, a straight type structure, an angled type structure, a curved type structure, or a folded type structure, or combinations thereof.

31. A semiconductor structure, comprising:
a dielectric structure formed in a substrate to a depth of at least about three microns or greater;
a first area, formed within said dielectric structure; and
a second area formed outside of said dielectric structure;
said substrate having a plurality of discontinuous gaps formed in the substrate along a first perimeter between said dielectric structure and said first area, and one or more gaps formed in the substrate along a second perimeter between the dielectric structure and the second area to provide stress relief between said dielectric structure and said first area or said second area, or combinations thereof.

32. A semiconductor structure as claimed in claim 31, said dielectric structure having a length or a width, or combinations thereof, of at least about five microns or greater.

33. A semiconductor structure as claimed in claim 31, said substrate having one or more silicon formations formed in said substrate between one or more of the gaps along the first perimeter or the second perimeter, or combinations thereof, to provide additional stress relief between said dielectric structure and said first area or said second area, or combinations thereof.

34. A semiconductor structure as claimed in claim 31, said first area comprising an active area or a field area, or combinations thereof.

35. A semiconductor structure as claimed in claim 31, said second area comprising an active area or a field area, or combinations thereof.

36. A semiconductor structure as claimed in claim 31, wherein the active area comprises one or more active devices formed thereon.

37. A semiconductor structure as claimed in claim 31, wherein one or more of the gaps of the plurality of gaps have a depth of about three microns to about 30 microns.

38. A semiconductor structure as claimed in claim 31, wherein one or more of the gaps of the plurality of gaps have a width of about 1 micron to about 1.5 microns.

39. A semiconductor structure as claimed in claim 33, said silicon formations comprising one or more of a chevron type structure, a triangular type structure, a conical type structure, a funnel type structure, a frustum type structure, a straight type structure, an angled type structure, a curved type structure, or a folded type structure, or combinations thereof.

40. A semiconductor structure as claimed in claim 31, one or more of the gaps of the plurality of gaps having sidewalls that have been smoothed or corners that have been rounded, or combinations thereof, via a hydrogen annealing process.

41. A semiconductor structure as claimed in claim 31, one or more of the gaps of the plurality of gaps being sealed and containing air, a gas, a vacuum, or a partial vacuum, or combinations thereof.

42. A semiconductor structure as claimed in claim 31, wherein said dielectric structure comprises one or more gaps at least partially refilled with an oxide material.

43. A semiconductor structure as claimed in claim 31, said dielectric structure comprising an embedded dielectric structure.

44. A semiconductor structure as claimed in claim 31, said dielectric structure having one or more passive devices formed thereon.

45. A method to form a semiconductor structure, comprising:
forming a dielectric structure in a semiconductor material, wherein the semiconductor material has a first surface and a second surface that is parallel to, or substantially parallel to, the first surface; and
wherein the forming of the dielectric structure comprises forming at least one trench in the semiconductor material that extends from the first surface of the semiconductor material to a distance of at least about three microns or greater towards the second surface and performing a hydrogen anneal process to shape a sidewall of the at least one trench.

46. A method as claimed in claim 45, further comprising forming one or more gaps abutting the dielectric structure about a perimeter of the dielectric structure.

47. A method as claimed in claim 45, further comprising forming an electrically conductive material over the dielectric structure and wherein said dielectric structure has a width of about at least three microns or greater.

48. A method as claimed in claim 47, further comprising forming at least a portion of an active device in the semiconductor material, wherein the active device is electrically coupled to the electrically conductive material.

49. A method as claimed in claim 45, wherein the dielectric structure comprises an oxide material, the semiconductor material comprises silicon, and at least a portion of the dielectric structure is embedded in the semiconductor material and extends from the first surface of the semiconductor material to a distance or at least about three microns or greater towards the second surface.
